(19) United States
(12) Patent Application Publication
(10) Pub. No.: US 2020/0388515 A1
(43) Pub. Date: Dec. 10, 2020

(54) SUBSTRATE PROCESSING APPARATUS, METHOD OF MANUFACTURING SEMICONDUCTOR DEVICE, AND RECORDING MEDIUM

(71) Applicant: KOKUSAI ELECTRIC CORPORATION, Tokyo (JP)

(72) Inventor: Yukitomo HIROCHI, Toyama-shi (JP)

(73) Assignee: KOKUSAI ELECTRIC CORPORATION, Tokyo (JP)

(21) Appl. No.: 17/001,056

(22) Filed: Aug. 24, 2020

Related U.S. Application Data
(63) Continuation of application No. PCT/JP2018/007837, filed on Mar. 1, 2018.

(51) Int. Cl. H01L 21/67; H01L 21/324; H01L 21/677

(52) U.S. Cl. CPC H01L 21/67115; H01L 21/67754; H01L 21/324

(57) ABSTRACT

There is provided a technique that includes: at least one process chamber configured to heat substrates; a cooling chamber configured to cool the substrates heated in the at least one process chamber; and a transfer machine configured to transfer the substrates, wherein the number of substrates loaded into the at least one process chamber by using the transfer machine is larger than the number of substrates loaded into the cooling chamber by using the transfer machine.

### CROSS-REFERENCE TO RELATED APPLICATION

This application is a Bypass Continuation Application of PCT International Application No. PCT/JP2018/007837, filed Mar. 1, 2018, the disclosure of which is incorporated herein in its entirety by reference.

### TECHNICAL FIELD

The present disclosure relates to a substrate processing apparatus, a method of manufacturing a semiconductor device, and a recording medium.

### BACKGROUND

As an example of a process of manufacturing a semiconductor device, for example, there is a modification process represented by an annealing process of heating a substrate in a process chamber by using a heating device to change a composition or a crystal structure of a thin film formed on a surface of the substrate or to repair crystal defects or the like in the formed thin film. In recent semiconductor devices, a modification process for a high-density substrate on which a pattern having a high aspect ratio is formed is required according to their remarkable miniaturization and high integration. A heat treatment method using electromagnetic waves is considered as such a modification process method for a high-density substrate.

In a process using electromagnetic waves of the related art, since it is necessary to provide a cooling process of cooling a substrate heated to a high temperature by heat treatment in a process chamber, productivity may be reduced.

### SUMMARY

The present disclosure provides some embodiments of an electromagnetic wave processing technique capable of suppressing a reduction in productivity even when a cooling process of a substrate is provided.

According to one embodiment of the present disclosure, there is provided a technique that includes: a process chamber configured to heat substrates; a cooling chamber configured to cool the substrates heated in the process chamber; and a transfer machine configured to transfer the substrates, wherein the number of substrates loaded into the process chamber by using the transfer machine is larger than the number of substrates loaded into the cooling chamber by using the transfer machine.

### BRIEF DESCRIPTION OF DRAWINGS

The accompanying drawings, which are incorporated in and constitute a part of the specification, illustrate embodiments of the present disclosure.

FIG. 1 is a vertical cross sectional view illustrating, at a location of a process furnace, a schematic configuration of a substrate processing apparatus suitably used in embodiments of the present disclosure.

FIG. 2 is a cross sectional view illustrating a schematic configuration of a substrate processing apparatus suitably used in embodiments of the present disclosure.

FIG. 3 is a schematic configuration diagram of a process furnace of a substrate processing apparatus suitably used in embodiments of the present disclosure, in which a portion of the process furnace is shown in a vertical cross-sectional view.

FIG. 4 is a vertical cross-sectional view illustrating, at a position of a cooling chamber, a schematic configuration of the substrate processing apparatus suitably used in embodiments of the present disclosure.

FIG. 5A is a diagram schematically illustrating a method of transferring a wafer to the cooling chamber, and FIG. 5B is a diagram schematically illustrating a method of unloading cooled wafers from the cooling chamber.

FIG. 6 is a diagram illustrating a purge gas circulation structure of a transfer chamber suitably used in embodiments of the present disclosure.

FIG. 7 is a schematic configuration diagram of a controller of the substrate processing apparatus suitably used in embodiments of the present disclosure.

FIG. 8 is a diagram illustrating a flow of substrate processing according to the present disclosure.

FIG. 9A is a diagram illustrating control contents of each part when an internal pressure of the transfer chamber is lowered by opening a gate valve in the process chamber, and FIG. 9B is a diagram illustrating control contents of each part when the internal pressure of the transfer chamber is raised by opening the gate valve in the process chamber.

### DETAILED DESCRIPTION

Reference will now be made in detail to various embodiments, examples of which are illustrated in the accompanying drawings. In the following detailed description, numerous specific details are set forth to provide a thorough understanding of the present disclosure. However, it will be apparent to one of ordinary skill in the art that the present disclosure may be practiced without these specific details. In other instances, well-known methods, procedures, systems, and components have not been described in detail so as not to unnecessarily obscure aspects of the various embodiments.

### Embodiments of the Present Disclosure

Embodiments of the present disclosure will now be described with reference to the drawings.

### (1) Configuration of Substrate Processing Apparatus

In the present embodiment, a substrate processing apparatus 100 according to the present disclosure is configured as a single-wafer-type heat treatment apparatus capable of performing various heat treatments on a single wafer or several wafers, and will be described as an apparatus configured to perform an annealing process (modification process) using electromagnetic waves as described below. In the substrate processing apparatus 100 according to the present embodiment, a front opening unified pod (FOUP, hereinafter, referred to as a pod) 110 is used as a storage vessel (carrier) in which wafers 200 as substrates is stored. The pod 110 is also used as a transfer vessel configured to be used in transferring the wafers 200 among various substrate processing apparatuses.

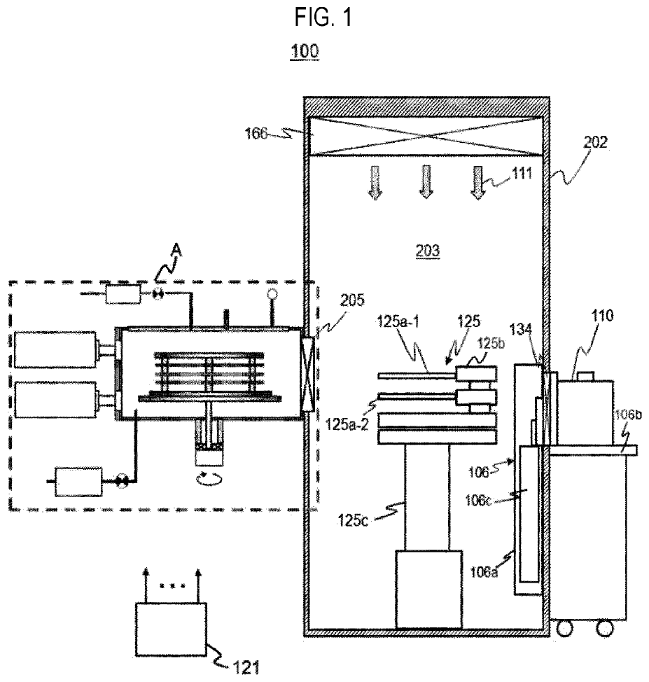

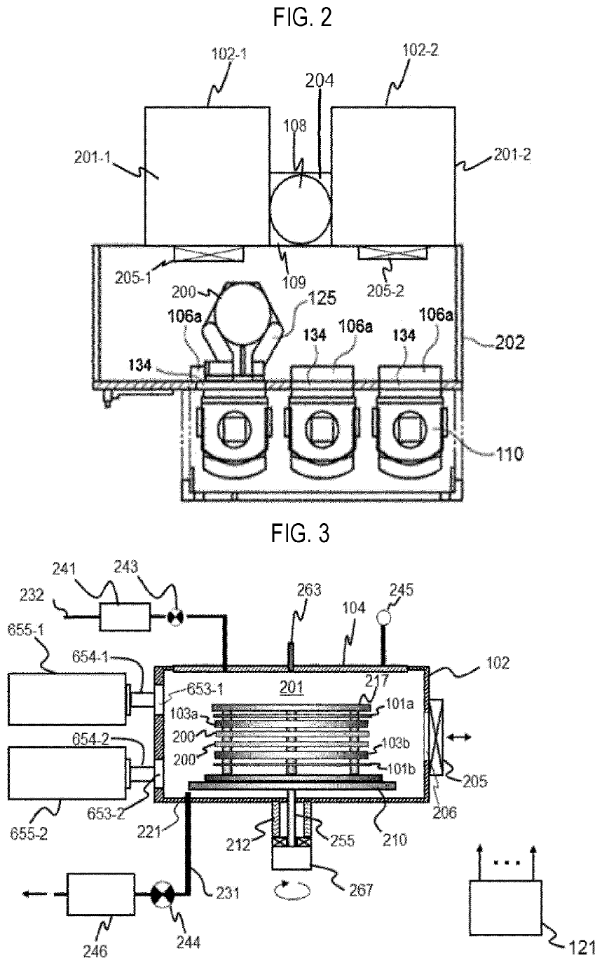

As illustrated in FIGS. 1 and 2, the substrate processing apparatus 100 includes a transfer housing (housing) 202 having therein a transfer chamber (transfer area) 203 configured to transfer the wafers 200, and cases 102-1 and 102-2 as process vessels, as described below, which are installed at a sidewall of the transfer housing 202 and respectively have process chambers 201-1 and 201-2 in which the wafers 200 are processed. In addition, a cooling case (a cooling vessel or a cooling housing) 109, which forms a cooling chamber 204 as described below, is installed between the process chambers 201-1 and 201-2. A load port unit (LP) 106 as a pod opening/closing mechanism configured to open and close a lid of the pod 110 to transfer and unload the wafers 200 into and from the transfer chamber 203 is disposed on the right side in FIG. 1 (the lower side in FIG. 2), which is a front side of the housing of the transfer chamber 203. The load port unit 106 includes a housing 106a, a stage 106b, and an opener 106c, in which the stage 106b is configured to mount the pod 110 to be close to a substrate loading/unloading port 134 formed in the front of the housing of the transfer chamber 203, and to open and close a lid (not shown) installed in the pod 110 by the opener 106c. Further, the load port unit 106 may have a function of purging an inside of the pod 110 with a purge gas such as an N₂ gas or the like. In addition, the housing 202 has a purge gas circulation structure, which will be described later, configured to circulate the purge gas such as N₂ or the like in the transfer chamber 203.

Gate valves (GVs) 205-1 and 205-2 configured to open and close the process chambers 201-1 and 201-2 are each disposed on the left side in FIG. 1 (the upper side in FIG. 2), which is a rear side of the housing 202 of the transfer chamber 203. A transfer machine 125, which serves as a substrate transfer mechanism (a substrate transfer robot or a substrate transfer part) configured to transfer the wafers 200, is installed at the transfer chamber 203. The transfer machine 125 includes tweezers (arms) 125a-1 and 125a-2 as mounting parts configured to mount the wafers 200, transfer devices 125b configured to be capable of horizontally rotating or linearly moving the respective tweezers (arms) 125a-1 and 125a-2, and a transfer device elevator 125c configured to raise or lower the transfer devices 125b. The wafers 200 may be charged on or discharged from a substrate support 217, which will be described later, the cooling chamber 204, and the pod 110 by continuous operation of the tweezers 125a-1 and 125a-2, the transfer devices 125b, and the transfer device elevator 125c. Hereinafter, the cases 102-1 and 102-2, the process chambers 201-1 and 201-2, and the tweezers 125a-1 and 125a-2 will be simply referred to as the case 102 and the process chamber 201, and the tweezers 125a, respectively, unless there is no need to describe them separately.

The tweezers 125a-1 are made of a normal aluminum material and are used in transferring the wafers at a low temperature and a room temperature. The tweezers 125a-2 are made of a material such as an aluminum or quartz member having high heat resistance and low heat conductivity, and are used in transferring the wafers at a high temperature and a room temperature. That is, the tweezers 125a-1 are a low temperature substrate transfer part (or a low temperature substrate transfer arm), and the tweezers 125a-2 are a high temperature substrate transfer part (or a high temperature substrate transfer arm). The tweezers 125a-2 for high temperature may be configured to have heat resistance of, for example, 100 degrees C. or higher, specifically 200 degrees C. or higher in some embodiments. A mapping sensor may be installed at the tweezers 125a-1 for low temperature. By installing the mapping sensor in the tweezers 125a-1 for low temperature, it is possible to confirm the number of wafers 200 in the load port unit 106, the number of wafers 200 in a reaction chamber 201, and the number of wafers 200 in the cooling chamber 204.

In the present embodiment, the tweezers 125a-1 will be described as low temperature tweezers, and the tweezers 125a-2 will be described as high temperature tweezers, but the present disclosure is not limited thereto. The tweezers 125a-1 are made of a material such as an aluminum or a quartz member having high heat resistance and low heat conductivity, and may be used in transferring the wafers at a high temperature and a room temperature, and the tweezers 125a-2 are made of a normal aluminum material, and may be used in transferring the wafers at a low temperature and a room temperature. Alternatively, both tweezers 125a-1 and 125a-2 may be made of a material such as aluminum or a quartz member having high heat resistance and low heat conductivity.

### Process Furnace

In a region A surrounded by a broken line in FIG. 1, a process furnace having a substrate processing structure as illustrated in FIG. 3 is configured. As illustrated in FIG. 2, a plurality of process furnaces are installed in the present embodiment, but since the process furnaces have the same configurations, only one configuration will be described and the description of the other process furnace configurations will be omitted.

As illustrated in FIG. 3, the process furnace includes a case 102 as a cavity (process vessel) made of a material such as metal or the like, which reflects electromagnetic waves. In addition, a cap flange (closing plate) 104 made of a metal material is configured to close an upper end of the case 102 via an O-ring (not shown) as a seal member. A space inside the case 102 and the cap flange 104 is mainly configured as the process chamber 201 in which a substrate such as a silicon wafer or the like is processed. A reaction tube (not shown) made of quartz, which transmits electromagnetic waves, may be installed inside the case 102, or the process vessel may be configured so that the inside of the reaction tube serves as the process chamber. Further, the process chamber 201 may be configured by using the case 102 whose ceiling is closed, instead of installing the cap flange 104.

A mounting stand 210 is installed in the process chamber 201, and a boat 217 serving as a substrate support configured to support wafers 200 as substrates is mounted on an upper surface of the mounting stand 210. The wafers 200 to be processed and quartz plates 101a and 101b as heat insulating plates held vertically above and below the wafers 200 to sandwich the wafers 200 are supported in the boat 217 at predetermined intervals. In addition, susceptors 103a and 103b (also referred to as energy conversion members, radiation plates, or uniform heat plates) which indirectly heat the wafers 200, each being formed of a dielectric substance such as dielectric or the like, which absorbs electromagnetic waves and is heated by itself, such as, a silicon plate (Si plate) or a silicon carbide plate (SiC plate), may be mounted between the quartz plates 101a and 101b and the wafers 200. With this configuration, the wafers 200 can be more efficiently and uniformly heated by radiant heat from the susceptors 103a and 103b. In the present embodiment, each of the quartz plates 101a and 101b and each of the susceptors 103a and 103b are formed of the same component, and they will be referred to as and described as the quartz plate 101 and the susceptor 103 below, respectively, unless there is no need to describe them separately.

The case 102 as the process vessel has, for example, a circular cross section, and is configured as a flat closed vessel. Further, a transfer housing 202 as a lower vessel is made of, for example, a metal material such as aluminum (Al) or stainless steel (SUS), or quartz. In addition, a space surrounded by the case 102 may be referred to as the process chamber 201 or the reaction area 201 as a process space, and a space surrounded by the transfer housing 202 may be referred to as the transfer chamber 203 or the transfer area 203 as a transfer space. Further, the process chamber 201 and the transfer chamber 203 are not limited to being configured to be horizontally adjacent to each other as in the present embodiment, but may be configured to be vertically adjacent to each other to raise or lower the substrate support having a predetermined structure.

As illustrated in FIGS. 1, 2 and 3, a substrate loading/unloading port 206 adjacent to the gate valve 205 is installed at the side surface of the transfer housing 202, and the wafers 200 are moved between the process chamber 201 and the transfer chamber 203 via the substrate loading/unloading port 206. As a countermeasure against leakage of electromagnetic waves as described below, a choke structure having a length of ¼ wavelength of electromagnetic waves to be used is installed around the gate valve 205 or the substrate loading/unloading port 206.

An electromagnetic wave supply part as a heating device, which will be described in detail later, is installed at the side surface of the case 102 so that the electromagnetic waves such as microwaves or the like supplied from the electromagnetic wave supply part are introduced into the process chamber 201 to heat the wafers 200 or the like and process the same.

The mounting stand 210 is supported by a shaft 255 as a rotary shaft. The shaft 255, which penetrates a bottom of the process chamber 201, is connected to a driving mechanism 267 configured to perform a rotation operation outside the process chamber 201. The wafers 200 mounted on the boat 217 can be rotated by operating the driving mechanism 267 to rotate the shaft 255 and the mounting stand 210. Further, a periphery of the lower end portion of the shaft 255 is covered with a bellows 212 so that the interior of the process chamber 201 and the transfer area 203 is hermetically kept.

In the present disclosure, the mounting stand 210 may be configured to be raised or lowered by the driving mechanism 267 so that the wafers 200 reach a wafer transfer position when the wafers 200 are transferred, and so that the wafers 200 reach a processing position (wafer processing position) in the process chamber 201 when the wafers 200 are processed, according to a height of the substrate loading/unloading port 206.

An exhaust part (or an exhauster) configured to exhaust an atmosphere of the process chamber 201 is installed below the process chamber 201 and on an outer peripheral side of the mounting stand 210. As illustrated in FIG. 1, an exhaust port 221 is installed at the exhaust part. An exhaust pipe 231 is connected to the exhaust port 221, and a pressure regulator 244 such as an APC valve or the like which controls an opening degree of the APC valve according to an internal pressure of the process chamber 201, and a vacuum pump 246 are sequentially connected in series to the exhaust pipe 231.

In the present disclosure, the pressure regulator 244 may be configured to use both an ordinary opening/closing valve and a pressure regulation valve, as well as the APC valve, as long as it can receive pressure information (a feedback signal from a pressure sensor 245 as described below) in the process chamber 201 and adjust an exhaust amount.

The exhaust part (also referred to as an exhaust system or an exhaust line) mainly includes the exhaust port 221, the exhaust pipe 231, and the pressure regulator 244. In addition, the exhaust port may be installed to surround the mounting stand 210 so that a gas can be exhausted from an entire circumference of the wafers 200. Further, the vacuum pump 246 may also be added to the configuration of the exhaust part.

A gas supply pipe 232 configured to supply various kinds of processing gases for the substrate processing, such as an inert gas, a precursor gas, a reaction gas and the like, into the process chamber 201 is installed at the cap flange 104.

A mass flow controller (MFC) 241, which is a flow rate controller (flow rate control part), and a valve 243, which is an opening/closing valve, are installed at the gas supply pipe 232 sequentially from upstream side. For example, a nitrogen (N₂) gas source of a nitrogen gas, which is an inert gas, is connected to the upstream side of the gas supply pipe 232 so that the nitrogen gas is supplied into the process chamber 201 via the MFC 241 and the valve 243. When using a plurality of kinds of gases during the substrate processing, the plurality of kinds of gases can be supplied by using a configuration in which a gas supply pipe in which the MFC, which is a flow rate controller, and the valve, which is an opening/closing valve, are installed is connected to the gas supply pipe 232 at the downstream side of the valve 243 sequentially from upstream side. A gas supply pipe in which an MFC and a valve are installed may be installed for each kind of gas.

A gas supply system (gas supply part) mainly includes the gas supply pipe 232, the MFC 241, and the valve 243. When an inert gas is allowed to flow through the gas supply system, it will also be referred to as an inert gas supply system. As the inert gas, it may be possible to use, in addition to the N₂ gas, a rare gas such as an Ar gas, an He gas, an Ne gas, an Xe gas or the like.

A temperature sensor 263 as a non-contact type temperature measuring device is installed in the cap flange 104. Based on temperature information detected by the temperature sensor 263, an output of a microwave oscillator 655, which will be described later, is adjusted such that the substrates are heated and the temperature of the substrates has a desired temperature distribution. The temperature sensor 263 is configured as a radiation thermometer such as an infrared radiation (IR) sensor or the like. The temperature sensor 263 is provided to measure a surface temperature of the quartz plate 101a or a surface temperature of the wafers 200. When the aforementioned susceptor serving as a heating element is installed, the temperature sensor 263 may be configured to measure a surface temperature of the susceptor. Further, in the present disclosure, when the “temperature of the wafers 200 (wafer temperature)” is described, it may indicate a wafer temperature converted by temperature conversion data as described below, that is, an estimated wafer temperature, a temperature obtained by measuring a temperature of the wafers 200 directly by the temperature sensor 263, or both of them.

The temperature conversion data, which indicates a correlation between the temperature of the quartz plate 101 or the susceptor 103 and the temperature of the wafers 200 by acquiring a transition of temperature change of each of the quartz plates 101 or the susceptors 103 and the wafers 200 in advance by the temperature sensor 263, may be stored in a memory device 121c or an external storage device 123. By creating the temperature conversion data in advance in this way, it is possible to estimate the temperature of the wafers 200 by measuring only the temperature of the quartz plate 101 or the susceptor 103, and to control the output of the microwave oscillator 655, that is, the heating device, based on the estimated temperature of the wafers 200.

Further, means configured to measure the temperature of the substrates is not limited to the radiation thermometer described above, but a thermocouple or both a thermocouple and a non-contact type thermometer may be used to measure the temperature. However, when measuring the temperature by using the thermocouple, the temperature is measured by disposing the thermocouple around the wafers 200. That is, since the thermocouple is disposed in the process chamber 201, the thermocouple itself may be heated by microwaves supplied from the microwave oscillator as described below, thus making it difficult to accurately measure the temperature. Accordingly, the non-contact type thermometer may be used as the temperature sensor 263 in some embodiments.

In addition, the temperature sensor 263 is not limited to being installed in the cap flange 104 but may be installed at the mounting stand 210. Further, the temperature sensor 263 is not only directly installed at the cap flange 104 or the mounting stand 210 but also may be configured to be indirectly measured by reflecting emitted light from a measurement window installed at the cap flange 104 or the mounting stand 210 with a mirror or the like. Further, the temperature sensor 263 is not limited to being installed as a single temperature sensor, but a plurality of temperature sensors 263 may also be installed.

Electromagnetic wave introduction ports 653-1 and 653-2 are installed on a sidewall of the case 102. One end of each of waveguides 654-1 and 654-2 configured to supply electromagnetic waves (microwaves) into the process chamber 201 is connected to each of the electromagnetic wave introduction ports 653-1 and 653-2. Each of microwave oscillators (electromagnetic wave sources) 655-1 and 655-2 as heating sources configured to supply electromagnetic waves into the process chamber 201 and heat the same is connected to the other end of each of the waveguides 654-1 and 654-2. The microwave oscillators 655-1 and 655-2 supply the electromagnetic waves such as microwaves or the like to the waveguides 654-1 and 654-2, respectively. Further, a magnetron, a klystron, or the like may be used as the microwave oscillators 655-1 and 655-2. Hereinafter, the electromagnetic wave introduction ports 653-1 and 653-2, the waveguides 654-1 and 654-2, and the microwave oscillators 655-1 and 655-2 will be referred to as and described as the electromagnetic wave introduction port 653, the waveguide 654, and the microwave oscillator 655, respectively, unless there is no need to describe them separately.

The frequency of the electromagnetic waves generated by the microwave oscillator 655 may be controlled to fall within a frequency range of 13.56 MHz or more and 24.125 GHz or less in some embodiments. Further, the frequency may be controlled to be 2.45 GHz or 5.8 GHz in some embodiments. In this case, the respective frequencies of the microwave oscillators 655-1 and 655-2 may have the same frequency or different frequencies.

Further, in the present embodiment, two microwave oscillators 655 are described to be disposed on the side surface of the case 102, but the present disclosure is not limited thereto and one or more microwave oscillators 655 may be installed and may be disposed to be installed on different side surfaces such as opposite side surfaces of the case 102. The electromagnetic wave supply part (also referred to as an electromagnetic wave supply device, a microwave supply part, or a microwave supply device) as the heating device mainly includes the microwave oscillators 655-1 and 655-2, the waveguides 654-1 and 654-2, and the electromagnetic wave introduction ports 653-1 and 653-2.

A controller 121 as described below is connected to each of the microwave oscillators 655 1 and 655-2. The temperature sensor 263 configured to measure the temperature of quartz plate 101a or 101b, or the wafers 200 accommodated in the process chamber 201 is connected to the controller 121. The temperature sensor 263 measures the temperature of the quartz plate 101 or the wafers 200 by the aforementioned method, and transmits the same to the controller 121 such that the controller 121 controls the outputs of the microwave oscillators 655-1 and 655-2 to control the heating of the wafers 200. Further, as the heating control method by the heating device, a method of controlling the heating of the wafers 200 by controlling a voltage input to the microwave oscillator 655, a method of controlling the heating of the wafers 200 by changing a ratio of a time for which the power source of the microwave oscillator 655 is turned on and a time for which the power source is turned off, or the like may be used.

The microwave oscillators 655-1 and 655-2 are controlled by the same control signal transmitted from the controller 121. However, the present disclosure is not limited thereto but may be configured so that the microwave oscillators 655-1 and 655-2 are individually controlled by respectively transmitting individual control signals from the controller 121 to the microwave oscillators 655-1 and 655-2.

### Cooling Chamber

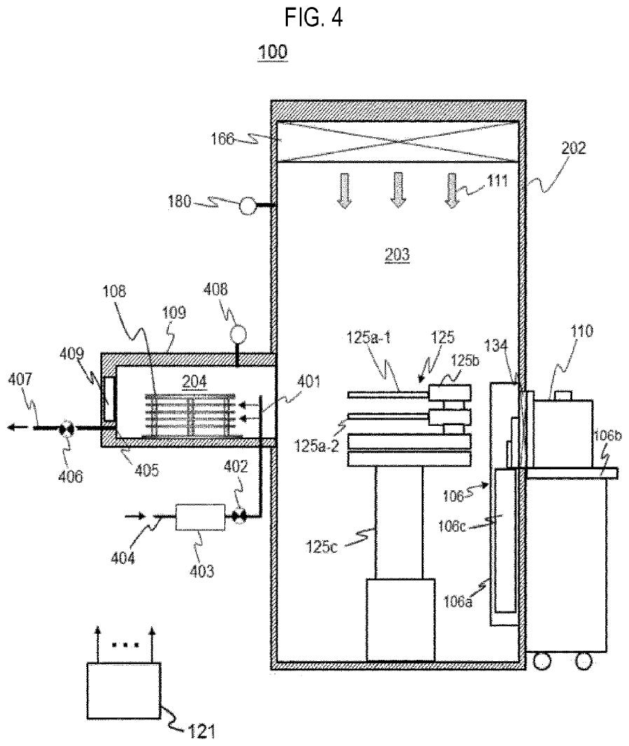

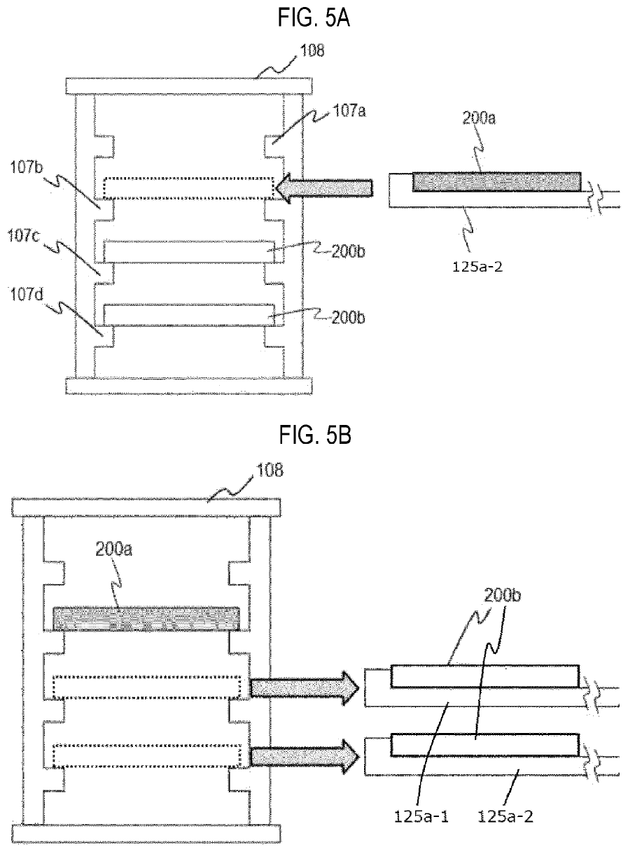

As illustrated in FIG. 2 and FIG. 4, a cooling chamber (also referred to as a cooling area or a cooling part) 204 as a cooling region, which cools the wafers 200 on which a predetermined substrate processing is performed, is formed by the cooling case 109 at a position which is on one side of the transfer chamber 203 and substantially equally distant from the process chambers 201 1 and 201-2 between the process chambers 201-1 and 201-2, specifically, such that transfer distances of the process chambers 201-1 and 201-2 from the substrate loading/unloading port 206, are substantially equal. A wafer cooling mount 108 (also referred to as a cooling stage, hereinafter, referred to as a CS) having the same structure as the boat 217 serving as the substrate support is installed in the cooling chamber 204. As illustrated in FIGS. 5A and 5B as described below, the CS 108 is configured to be capable of horizontally supporting a plurality of wafers 200 in multiple stages along a vertical direction by a plurality of wafer holding grooves 107a to 107d. In addition, a gas supply nozzle (cooling chamber gas supply nozzle) 401 as a cooling chamber purge gas supply part configured to supply an inert gas as a purge gas (purge gas for cooling chamber) that purges an internal atmosphere of the cooling chamber 204 at a predetermined first gas flow rate via a gas supply pipe (cooling chamber gas supply pipe) 404 is provided at the cooling case 109. The gas supply nozzle 401 may be an opening nozzle whose end is opened, or a porous nozzle in which a plurality of gas supply ports are installed at a sidewall of the nozzle facing the CS 108 may be used in some embodiments. Further, a plurality of gas supply nozzles 401 may be installed. Further, the purge gas supplied from the gas supply nozzle 401 may be used as a cooling gas that cools the processed wafers 200 mounted on the CS 108.

As illustrated in FIG. 2, the cooling chamber 204 may be installed between the process chamber 201-1 and the process chamber 201-2 in some embodiments. Thus, it is possible to make a moving distance (moving time) between the process chamber 201-1 and the cooling chamber 204 equal to a moving distance between the process chamber 201-2 and the cooling chamber 204, thereby having the same tact time. Further, it is possible to improve a transfer throughput by installing the cooling chamber 204 between the process chamber 201-1 and the process chamber 201-2.

The CS 108 installed in the cooling chamber 204 can support four wafers 200, as illustrated in FIGS. 5A and 5B. That is, the CS 108 is configured to be capable of cooling at least twice (4 wafers) the number of wafers 200 (2 wafers) heated in the process chamber 201-1 or 201-2.

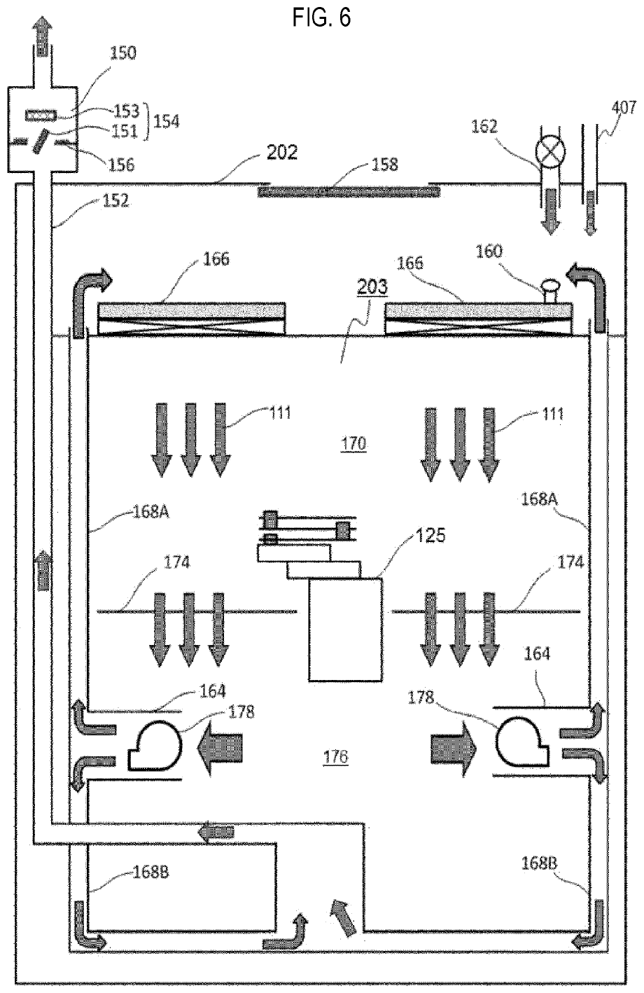

In addition, an exhaust port 405 configured to exhaust the purge gas for cooling chamber, an opening/closing valve (or an APC valve) 406 as a cooling chamber exhaust valve for configured to adjust the exhaust amount of the gas, and an exhaust pipe 407 as a cooling chamber exhaust pipe are installed in the cooling chamber 204. A cooling chamber vacuum pump (not shown) configured to positively exhaust the internal atmosphere of the cooling chamber 204 may be installed at the exhaust pipe 407 at the rear stage of the opening/closing valve 406. The exhaust pipe 407 may be connected to a purge gas circulation structure configured to circulate the internal atmosphere of the transfer chamber 203, which will be described later, for circulation. In that case, the exhaust pipe 407 may be connected to a circulation passage 168A illustrated in FIG. 6, which will be described later, or may be connected (joined) to a downstream position of the circulation passage 168A and an upstream position just before clean units 166.

Further, a cooling chamber pressure sensor (a cooling chamber pressure meter) 408 which detects the internal pressure of the cooling chamber 204 is installed in the cooling case 109, and an MFC 403 as a cooling chamber MFC and a valve 402 as a cooling chamber valve are controlled by the controller 121 described later to make the internal pressure of the transfer chamber detected by a transfer chamber pressure sensor (a transfer chamber pressure meter) 180 and a differential pressure in the cooling chamber 204 constant, such that the purge gas is supplied or the supply of purge gas is stopped. Further, the opening/closing valve 406 and the cooling chamber vacuum pump are controlled to control exhaust of the purge gas or stop of the exhaust of purge gas. By these controls, an internal pressure of the cooling chamber 204 and the temperature of the wafers 200 mounted on the CS 108 are controlled. Further, a cooling chamber gas supply system (first gas supply part) mainly includes the gas supply nozzle 401, the valve 402, the MFC 403, and the gas supply pipe 404, and a cooling chamber gas exhaust system (cooling chamber gas exhaust part) mainly includes the exhaust port 405, the opening/closing valve 406, and the exhaust pipe 407. The cooling chamber vacuum pump may be included in the cooling chamber gas exhaust system. In addition, a temperature sensor (not shown) configured to measure the temperature of the wafers 200 mounted on the CS 108 may be installed in the cooling chamber 204. Each of the wafer holding grooves 107a to 107d will be simply referred to herein as the wafer holding groove 107 unless it is necessary to describe them separately.

### Purge Gas Circulation Structure

Next, a purge gas circulation structure installed in the transfer chamber 203 of the present embodiment will be described with reference to FIGS. 1 and 6. As illustrated in FIG. 6, the transfer chamber 203 includes a purge gas supply mechanism (second gas supply part) 162 configured to supply an inert gas as a purge gas or air (fresh air) into a duct formed around the transfer chamber 203 at a predetermined second gas flow rate, and a pressure control mechanism 150 configured to control the internal pressure of the transfer chamber 203. The purge gas supply mechanism 162 is configured to supply the purge gas into the duct according to a detection value of a detector 160 which mainly detects an oxygen concentration in the transfer chamber 203. The detector 160 is installed above (at an upstream side of) the clean units 166 as a gas supply mechanism configured to remove dust or impurity and supplies a purge gas into the transfer chamber 203. The clean units 166 each includes a filter configured to remove dust or impurity and a blower (fan) configured to blow the purge gas. By the purge gas supply mechanism 162 and the pressure control mechanism 150, it is possible to control the oxygen concentration in the transfer chamber 203. In the present disclosure, the detector 160 may be configured to detect a moisture concentration, in addition to the oxygen concentration.

The pressure control mechanism 150 includes an adjustment damper 154 configured to keep the interior of the transfer chamber 203 at a predetermined pressure, and an exhaust damper 156 configured to fully open or fully close an exhaust passage 152. The adjustment damper 154 includes an automatic damper (back pressure valve) 151 configured to be opened when the internal pressure of the transfer chamber 203 is higher than the predetermined pressure, and a press damper 153 configured to control opening and closing of the automatic damper 151. By controlling the opening and closing of the adjustment damper 154 and the exhaust damper 156 in this way, it is possible to control the interior of the transfer chamber 203 to an arbitrary pressure.

As illustrated in FIG. 6, the clean units 166 are disposed on a ceiling of the transfer chamber 203 one by one on the left and right sides. A porous plate 174, which is a distribution plate configured to distribute the flow of the purge gas, is provided around the transfer machine 125. The porous plate 174 has a plurality of holes and is formed of, for example, a punching panel. A space in the transfer chamber 203 is partitioned into a first space 170 as an upper space and a second space 176 as a lower space by installing the porous plate 174. That is, the first space 170, which is a wafer transfer region, is formed in a space between the ceiling portion and the porous plate 174, and the second space 176 which is a gas exhaust region is formed in a space between the porous plate 174 and the floor surface of the transfer chamber 203.

Suction parts 164 configured to circulate and exhaust the purge gas flowing through the transfer chamber 203 are disposed one by one on the left and right sides with the transfer machine 125 interposed therebetween in the lower portion of the second space 176 below the transfer chamber 203. In addition, passages 168 serving as a circulation passage and an exhaust passage respectively connecting a pair of left and right suction parts 164 and a pair of left and right filter units 166 are formed at the wall surface of the housing 202, that is, between the outer wall surface and the inner wall surface of the housing 202. By installing a cooling mechanism (radiator) (not shown) configured to cool a fluid in the passages 168, the temperature control of the circulation purge gas becomes possible.

The passages 168 are branched into two passages: a circulation passage 168A which is the circulation passage; and an exhaust passage 168B. The circulation passage 168A is a flow passage which is connected to the upstream side of the clean units 166 and configured to supply the purge gas again into the transfer chamber 203. The exhaust passage 168B is a flow passage which is connected to the pressure control mechanism 150 and configured to exhaust the purge gas, and the exhaust passage 168B installed on the left and right sides of the housing 202 is joined to one external exhaust passage 152 on the downstream side.

Next, the flow of the gas in the transfer chamber 203 will be described. The arrows indicated in FIG. 6 schematically show the flow of the purge gas supplied from the purge gas supply mechanism 162. For example, when an N₂ gas (inert gas) as the purge gas is introduced into the transfer chamber 203, the N₂ gas is supplied from the ceiling of the transfer chamber 203 into the transfer chamber 203 via the clean units 166 to form a downflow 111 in the transfer chamber 203. The porous plate 174 is installed in the transfer chamber 203, and the space in the transfer chamber 203 is mainly partitioned into a first space 170 which is a region where the wafers 200 are transferred and a second space 176 where particles are likely to sink, such that a structure in which a differential pressure is formed between the first space 170 and the second space 176. At this time, the pressure of the first space 170 is higher than the pressure of the second space 176. With this configuration, it is possible to prevent the particles generated from the driving part such as the transfer device elevator 125c below the tweezers 125a from scattering into the wafer transfer region. Further, it is possible to prevent the particles on the floor surface of the transfer chamber 203 from being wound up into the first space 170.

The N₂ gas supplied to the second space 176 by the downflow 111 is sucked out from the transfer chamber 203 by the suction parts 164. The N₂ gas sucked out from the transfer chamber 203 is divided into two flow passages of the circulation passage 168A and the exhaust passage 168B at the downstream side of the suction parts 164. The N₂ gas introduced into the circulation passage 168A flows over the housing 202 and is circulated in the transfer chamber 203 via the clean units 166. Further, the N₂ gas introduced into the exhaust passage 168B flows below the housing 202 and is exhausted to the outside from the external exhaust passage 152. In the present disclosure, when the conductance of the circulation passage 168A is small, fans 178 as blowers configured to promote the circulation of the N₂ gas may be installed in the left and right suction parts 164. By installing the fans 178, it is possible to improve the flow of the N₂ gas and to easily form the circulating air flow. By performing the circulation and exhaust separately for the left and right two systems in this way, it is possible to form a uniform air flow in the transfer chamber 203.

In the present disclosure, whether or not to circulate the N₂ gas in the transfer chamber 203 may be made by controlling the opening and closing of the adjustment damper 154 and the exhaust damper 156. That is, when circulating the N₂ gas in the transfer chamber 203, the automatic damper 151 and the press damper 153 may be opened and the exhaust damper 156 may be closed such that the circulation air flow into the transfer chamber 203 is easily formed. In this case, N₂ gas introduced into the exhaust passage 168B may remain in the exhaust passage 168B or flow into the circulation passage 168A.

In this case, the internal pressure of the pod 110, the internal pressure of the transfer chamber 203, the internal pressure of the process chamber 201, and the internal pressure of the cooling chamber 204 are all controlled by the controller 121 at an atmospheric pressure or at a pressure of about 10 to 200 Pa (gauge pressure) higher than the atmospheric pressure. Furthermore, in each of an in-furnace pressure and temperature adjustment step S803, an inert gas supply step S804, and a modification step S805, which will be described later, the internal pressure of the transfer chamber 203 may be controlled to be higher than the pressures of the process chamber 201 and the cooling chamber 204, and the internal pressure of the process chamber 201 may be controlled to be higher than the internal pressure of the pod 110. In each of a substrate loading step S802, a substrate unloading step S806, and a substrate cooling step S807, the internal pressure of the transfer chamber 203 may be controlled to be lower than the internal pressure of the process chamber 201 and higher than the internal pressure of the cooling chamber 204.

### Control Device

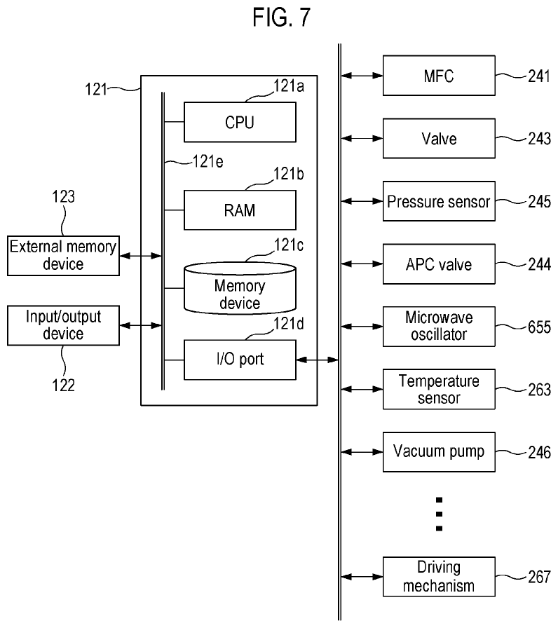

As illustrated in FIG. 7, the controller 121, which is a control part (a control device or a control means), may be configured as a computer including a central processing unit (CPU) 121a, a random access memory (RAM) 121b, a memory device 121c, and an I/O port 121d. The RAM 121b, the memory device 121c, and the I/O port 121d are configured to exchange data with the CPU 121a via an internal bus 121e. An input/output device 122 configured as, for example, a touch panel or the like, is connected to the controller 121.

The memory device 121c includes, for example, a flash memory, a hard disk drive (HDD), or the like. A control program that controls operations of a substrate processing apparatus, a process recipe that describes sequences and conditions of an annealing (modification) process, or the like is readably stored in the memory device 121c. The process recipe functions as a program that causes the controller 121 to execute each sequence in the substrate processing described below to obtain a predetermined result. Hereinafter, the process recipe, the control program, and the like will be generally and simply referred to as a “program.” Further, the process recipe will be simply referred to as a “recipe.” When the term “program” is used herein, it may indicate a case of including only the recipe, a case of including only the control program, or a case of including both the recipe and the control program. The RAM 121b is configured as a memory area (work area) in which a program, data and the like read by the CPU 121a is temporarily stored.

The I/O port 121d is connected to the MFC 241, the valve 243, the pressure sensor 245, the APC valve 244, the vacuum pump 246, the temperature sensor 263, the driving mechanism 267, the microwave oscillator 655, and the like.

The CPU 121a is configured to read the control program from the memory device 121c and execute the same. The CPU 121a also is further configured to read the recipe from the memory device 121c according to an input of an operation command from the input/output device 122. In addition, the CPU 121a is configured to control, according to the contents of the recipe thus read, the flow rate adjusting operation of various kinds of gases by the MFC 241, the opening/closing operation of the valve 243, the pressure regulating operation performed by the APC valve 244 based on the pressure sensor 245, the driving and stopping of the vacuum pump 246, the output adjusting operation performed by the microwave oscillator 655 based on the temperature sensor 263, and the operation of rotating and adjusting the rotation speed of the mounting stand 210 (or the boat 217) or operation of raising or lowering the mounting stand 210 with the driving mechanism 267, and the like.

The controller 121 may be configured by installing, on the computer, the aforementioned program stored in the external memory device 123 (for example, a magnetic disc such as a hard disk, an optical disc such as a CD, a magneto-optical disc such as an MO, or a semiconductor memory such as a USB memory). The memory device 121c or the external memory device 123 is configured as a computer-readable recording medium. Hereinafter, the memory device 121c and the external memory device 123 will be generally and simply referred to as a “recording medium.” When the term “recording medium” is used herein, it may indicate a case of including only the memory device 121c, a case of including only the external memory device 123, or a case of including both the memory device 121c and the external memory device 123. Furthermore, the program may be supplied to the computer by using a communication means such as the Internet or a dedicated line, instead of using the external memory device 123.

### (2) Substrate Processing

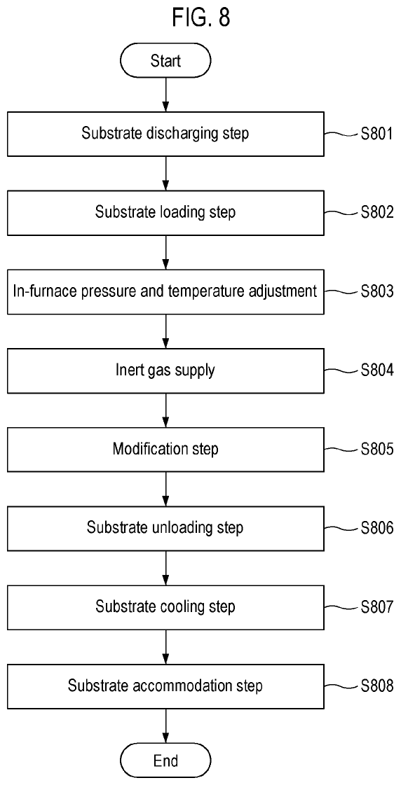

Next, for example, an example of a method of modifying (crystallizing) an amorphous silicon film as a silicon-containing film formed on a substrate by using the process furnace of the aforementioned substrate processing apparatus 100, which is one of processes for manufacturing a semiconductor device, will be described according to a process flow illustrated in FIG. 8. In the following descriptions, the operations of the respective parts constituting the substrate processing apparatus 100 are controlled by the controller 121. Furthermore, even in the substrate processing of the present embodiment as in the process furnace structure described above, since the same recipe is used in the plurality of process furnaces installed for the processing contents, i.e., the recipe, only the substrate processing using one process furnace will be described and the description of the substrate processing using the other process furnaces will be omitted.

When the term “wafer” is used herein, it may refer to a wafer itself or a laminated body of a wafer and a predetermined layer or film formed on the surface of the wafer. In addition, when the phrase “a surface of a wafer” is used herein, it may refer to a surface of a wafer itself or a surface of a predetermined layer or the like formed on a wafer. Furthermore, in the present disclosure, the expression “a predetermined layer is formed on a wafer” may mean that a predetermined layer is directly formed on a surface of a wafer itself or that a predetermined layer is formed on a layer or the like formed on a wafer. In addition, when the term “substrate” is used herein, it may be synonymous with the term “wafer.”

### Substrate Discharging Step (S801)

As illustrated in FIG. 1, the transfer machine 125 discharges a predetermined number of wafers 200 to be processed from the pod 110 opened by the load port unit 106, and mounts the wafers 200 on both tweezers 125a-1 and 125a-2. That is, the two wafers are mounted on a low temperature tweezer 125a-1 and a high temperature tweezer 125a-2, and the two wafers are discharged from the pod 110.

### Substrate Loading Step (S802)

As illustrated in FIG. 3, the wafers 200 mounted on both the tweezers 125a-1 and 125a-2 are loaded into a predetermined process chamber 201 by the opening/closing operation of the gate valve 205 (boat loading). That is, the two wafers mounted on the low temperature tweezer 125a 1 and the high temperature tweezer 125a-2 are loaded into the process chamber 201.

### In-furnace Pressure and Temperature Adjustment Step (S803)

After the loading of the boat 217 into the process chamber 201 is completed, the internal atmosphere of the process chamber 201 is controlled so that the interior of the process chamber 201 has a predetermined pressure (for example, 10 to 102,000 Pa). Specifically, the valve opening degree of the pressure regulator 244 is feedback-controlled based on the pressure information detected by the pressure sensor 245 while performing an exhaust by the vacuum pump 246 such that the interior of the process chamber 201 becomes equal to the predetermined pressure. At the same time, as pre-heating, the electromagnetic wave supply part may be controlled to perform a heating to a predetermined temperature (S803). When the temperature is raised to a predetermined substrate processing temperature by the electromagnetic wave supply part, the temperature may be raised with an output smaller than an output of a modification step described below so that the wafers 200 are not deformed or damaged. Further, when the substrate processing is performed under an atmospheric pressure, only the in-furnace temperature adjustment may be performed while the in-furnace pressure regulation is not performed, and then the process may proceed to the inert gas supply step S804 described below.

### Inert Gas Supply Step (S804)

When the internal pressure and the internal temperature of the process chamber 201 are controlled to predetermined values at the in-furnace pressure and temperature adjustment step S803, the driving mechanism 267 rotates the wafers 200 via the boat 217 on the mounting stand 210 by rotating the shaft 255. At this time, an inert gas such as nitrogen gas is supplied via the gas supply pipe 232 (S804). Further, at this time, the internal pressure of the process chamber 201 is adjusted to a predetermined value which falls within a range of 10 Pa or more and 102,000 Pa or less, for example, 101,300 Pa or more and 101,650 Pa or less. The shaft may also be rotated during the substrate loading step S402, that is, after the loading of the wafers 200 into the process chamber 201 is completed.

### Modification Step (S805)

When the interior of the process chamber 201 is kept at a predetermined pressure, the microwave oscillator 655 supplies microwaves into the process chamber 201 via the respective parts described above. By supplying the microwaves into the process chamber 201, the wafers 200 are heated to a temperature of 100 degrees C. or higher and 1,000 degrees C. or lower, specifically a temperature of 400 degrees C. or higher and 900 degrees C. or lower in some embodiments, or specifically a temperature of 500 degrees C. or higher and 700 degrees C. or lower in some embodiments. By performing the substrate processing at such a temperature, the substrate processing is performed at a temperature at which the wafers 200 efficiently absorb the microwaves, thereby improving a speed of the modification step. In other words, when the wafers 200 are processed at a temperature lower than 100 degrees C. or at a temperature higher than 1,000 degrees C., the surfaces of the wafers 200 may be deteriorated and the microwaves may be hardly absorbed, making it difficult to heat the wafers 200. Therefore, the substrate processing may be performed in a temperature zone as described above.

In the present embodiment in which heating is performed by the microwave heating method, a standing wave is generated in the process chamber 201, a heating concentration region (hot spot) which is locally heated and a region which is not heated (non-heating region), other than the heating concentration region are generated on the wafers 200 (the same applies to the susceptor 103 when the susceptor 103 is mounted), and the generation of the hot spot on the wafers 200 is suppressed by controlling ON/OFF of the power source of the electromagnetic wave supply part to prevent deformation of the wafers 200 (the same applies to the susceptor 103 when the susceptor 103 is mounted). At this time, the deformation of the wafers 200 can also be suppressed by controlling the power supply of the electromagnetic wave supply part to a low output so that the influence of the hot spot is reduced. However, in this case, since an energy applied to the wafers 200 or the susceptor 103 is decreases, a temperature rise also decreases, and therefore a heating time increases.

In this case, as described above, the temperature sensor 263 is a non-contact type temperature sensor, and when the wafers 200 (the same applies to the susceptor 103 when the susceptor 103 is mounted) to be measured are deformed or damaged, since a position of the wafer 200 monitored by the temperature sensor or a measurement angle with respect to the wafer 200 changes, a measurement value (monitor value) may become inaccurate and a measured temperature may change rapidly. In the present embodiment, the rapid change in the measured temperature of the radiation thermometer accompanying such deformation or damage of the measurement target is used as a trigger for turning on and off the electromagnetic wave supply part.

By controlling the microwave oscillator 655 as described above, the wafers 200 are heated to modify (crystallize) the amorphous silicon film formed on the surface of each of the wafers 200 into a polysilicon film (S805). That is, the wafers 200 can be uniformly modified. In addition, when the measured temperature of the wafers 200 becomes higher or lower than the aforementioned threshold value, the temperature of the wafers 200 may become a temperature which falls within a predetermined range by controlling the output of the microwave oscillator 655 to decrease, instead of turning off the microwave oscillator 655. In this case, when the temperature of the wafers 200 is returned to the temperature within the predetermined range, the output of the microwave oscillator 655 is controlled to increase.

After the lapse of a preset processing time, the rotation of the boat 217, the gas supply, the microwave supply and the exhaust pipe exhaust are stopped.

### Substrate Unloading Step (S806)

After the internal pressure of the process chamber 201 is returned to an atmospheric pressure, the gate valve 205 is opened to spatially communicate the process chamber 201 and the transfer chamber 203 with each other. Thereafter, one heated (processed) wafer 200 mounted on the boat 217 is unloaded to the transfer chamber 203 by the high temperature tweezers 125a-2 of the transfer machine 125 (S806).

### Substrate Cooling Step (S807)

The one heated (processed) wafer 200 unloaded by the high temperature tweezers 125a-2 is moved to the cooling chamber 204 by continuous operation of the transfer device 125b and the transfer device elevator 125c, and is mounted on the CS 108 by the high temperature tweezers 125a-2. Specifically, as illustrated in FIG. 5A, a wafer 200a after the modification step S805 held by the high temperature tweezers 125a-2 is transferred to the wafer holding groove 107b installed in the CS 108 and is mounted for a predetermined time to cool the wafer 200a (S807). At this time, as illustrated in FIG. 5B, when the wafer 200b previously cooled by the CS 108 is mounted, the high temperature tweezers 125a-2 and the low temperature tweezers 125a-1 transfer two cooled wafers 200b, after the wafer 200a upon completion of the modification step S805 is mounted on the wafer holding groove 107b, to the load port, that is, the pod 110.

When the two wafers 200 are heated (processed) on the boat 217 in the process chamber 201 in batch, the substrate unloading step (S806) and the substrate cooling step (S807) are continuously performed a plurality number of times (twice in this example) such that two high-temperature wafers 200a are mounted on the CS 108 one by one by the high temperature tweezers 125a-2. At this time, when the two cooled wafers 200b are mounted on the CS 108, the two cooled wafers 200b are unloaded from the CS 108 to the pod 110 by the high temperature tweezers 125a-2 and the low temperature tweezers 125a-1. Therefore, since the time for which the high temperature tweezers 125a-2 hold the high-temperature wafers 200a can be shortened, it is possible to reduce a heat load on the transfer machine 125. Further, it is possible to prolong the time for cooling the wafers 200.

As described above, high temperature the tweezers 125a-2 are installed, and the heated (processed) high-temperature wafers 200a in the process chamber 201 are not cooled in the process chamber 201 to, for example, 100 degrees C. or lower, but are moved to the CS 108 in the cooling chamber 204 by using the high temperature tweezers 125a-2 while keeping a relatively high temperature. Therefore, since the mounting time of the wafers 200 in the process chamber 201 can be shortened, it is possible to improve a usage efficiency of the process chamber 201 and to improve a productivity in the modification step of the wafers 200, and the like. As a method of cooling the high-temperature wafers 200a in the process chamber 201 to, for example, 100 degrees C. or lower, a method of forcibly cooling the wafers 200 to be 100 degrees C. or lower by using an inert gas such as nitrogen (N₂) or the like may also be used. However, in the present embodiment, since such forcible cooling by using the inert gas is not used, it is also possible to reduce the usage amount of the inert gas.

Further, when the wafers 200a are mounted in the wafer holding grooves (107a, 107b, 107c, and 107d) of the cooling chamber 204, subsequent heated high-temperature wafers 200a may be mounted just below or just above the heated (processed) high-temperature wafers 200, which was mounted previously. By doing so, management for discharging the wafers 200b cooled in the cooling chamber 204 is facilitated.

### Substrate Accommodation Step (S808)

For the wafers 200 cooled by the substrate cooling step S807, the two wafers cooled by the low temperature tweezers 125a-1 and the high temperature tweezers 125a-2 are discharged from the cooling chamber 204 and transferred to a predetermined pod 110. By combining the one-wafer transfer (loading into the cooling chamber 204) and the two-wafer transfer (unloading from the cooling chamber 204) in this way, it is possible to shorten the transfer time of the wafers 200.

By repeating the aforementioned operations, the wafers 200 are modified and transferred to the next substrate processing step. In addition, it has been described that the substrate processing is performed by mounting two wafers 200 on the boat 217, but the present disclosure is not limited thereto and the same processing may be performed while mounting the wafers 200 one by one on the boats 217 respectively installed in the process chambers 201-1 and 201-2, or swap processing may be performed to process two wafers 200 in the process chambers 201-1 and 201-2. At this time, transfer destinations of the wafers 200 may be controlled so that the numbers of times of substrate processing respectively performed in the process chambers 201-1 and 201-2 are identical. By performing control in this way, the number of times of substrate processing performed in each of the process chambers 201-1 and 201-2 becomes constant, whereby maintenance work such as maintenance can be efficiently performed. For example, if the process chamber where the wafer 200 was transferred previously is the process chamber 201 1, transfer destination of the next wafer 200 is controlled to be the process chamber 201-2 such that the number of times of substrate processing in each of the process chambers 201-1 and 201-2 can be controlled.

When performing the same processing by mounting the wafers one by one on the boats 217 respectively installed in the process chambers 201-1 and 201-2, the low temperature tweezers 125a-1 and the high temperature tweezers 125a-2 may be used as follows. Two wafers 200 are discharged from the load port unit 106 by the low temperature tweezers 125a-1 and the high temperature tweezers 125a-2, and for example, one wafer 200 mounted on the low temperature tweezers 125a-1 is loaded into the process chamber 201-1 and one wafer 200 mounted on the high temperature tweezers 125a-2 is loaded into the process chamber 201-2. Thereafter, when the heating process is completed, one heated (processed) wafer 200a is discharged from the process chamber 201-1 by the high temperature tweezers 125a-2 and loaded into the cooling chamber 204, and one heated (processed) wafer 200a is discharged from the process chamber 201 2 by the high temperature tweezers 125a-2 and loaded into the cooling chamber 204.

### (3) Pressure Control in the Cooling Chamber

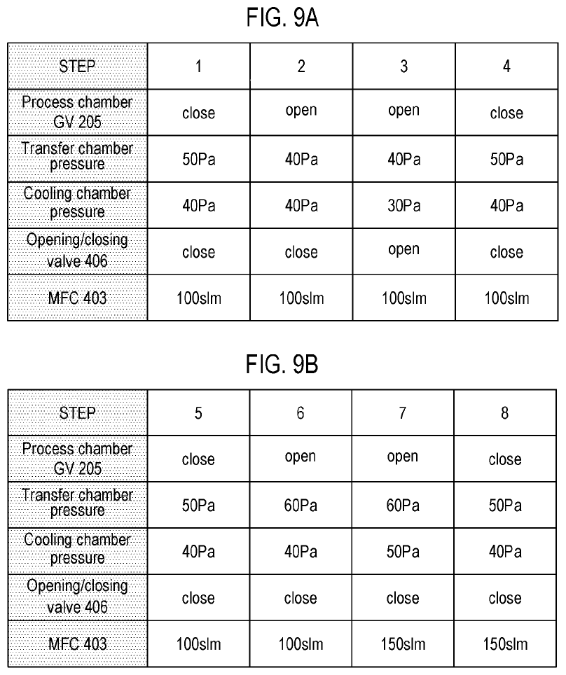

Next, pressure control in the cooling chamber 204 will be described with reference to FIGS. 9A and 9B. In the following description, the operations of the respective parts are controlled by the controller 121, as in the substrate processing.

As illustrated in FIG. 4, a partition wall such as the gate valve 205 which spatially isolates the process chamber 201 from the transfer chamber 203 is not installed in the cooling chamber 204 of the present embodiment. Therefore, a change occurs in the flow of the purge gas flowing through the transfer chamber 203 according to an internal pressure of the cooling chamber 204. Since the change in the gas flow in the transfer chamber 203 causes turbulence of the purge gas in the transfer chamber 203, causes winding up of particles in the transfer chamber, or causes wafer shift during wafer transfer, adverse effects such as deterioration in quality of a resultant film as formed and deterioration in throughput may be generated. A pressure control may be performed in the cooling chamber 204 to suppress these adverse effects. The flow rate of the purge gas supplied into the transfer chamber 203 is controlled to be higher than the flow rate of the purge gas supplied to the cooling chamber 204 to perform the pressure control.

In this case, the flow rate of the purge gas supplied into the transfer chamber 203 may be 100 slm or more and 2,000 slm or less in some embodiments. In a case where the gas is supplied at a flow rate lower than 100 slm, it is difficult to completely purge the interior of the transfer chamber 203, making impurity or byproduct remain in the transfer chamber 203. Further, in a case where the gas is supplied at a flow rate higher than 2000 slm, the wafer 200 mounted at a predetermined position may be shifted when the wafer 200 is transferred by the transfer machine 125, or turbulence such as vortex may be generated at a corner part or the like of the transfer housing 202, causing the impurity such as particles to be wound up.

In addition, in the case where the flow rate is set as the flow rate of the gas supplied into the transfer chamber 203 as described above, the flow rate of the purge gas supplied into the cooling chamber 204 may be set at a flow rate of 10 slm or more and 800 slm or less in some embodiments. In a case where the gas is supplied at a flow rate lower than 10 slm, it may be difficult to completely purge the interior of the cooling chamber 204, making the impurity or byproduct remain in the transfer chamber 203. Further, in a case where the gas is supplied at a flow rate higher than 800 slm, the wafer 200 mounted at a predetermined position may be shifted when the wafer 200 is transferred by the transfer machine 125, or turbulence such as vortex may be generated at a corner part or the like of the cooling case 109, causing the impurity such as particles to be wound up.

When controlling the internal pressure of the transfer chamber 203 and the internal pressure of the cooling chamber 204, for example, the internal pressure value of the transfer chamber 203 detected by the transfer chamber pressure sensor 180 may be controlled to be always higher than the internal pressure value of the cooling chamber 204 detected by the cooling chamber pressure sensor 408 in some embodiments. That is, the internal pressure of the transfer chamber 203 may be controlled to be higher than the internal pressure of the cooling chamber 204 in some embodiments. At this time, in particular, by controlling a pressure difference between the transfer chamber 203 and the cooling chamber 204 to be higher than 0 Pa and not higher than 100 Pa, it is possible to minimize an influence of the internal pressure of the cooling chamber 204 on the purge gas flow in the transfer chamber 203. In a case where the pressure difference between the transfer chamber 203 and the cooling chamber 204 is 0 Pa, the pressure difference between the transfer chamber 203 and the cooling chamber 204 is eliminated and the purge gas supplied to the cooling chamber flows may back into the transfer chamber 203, causing a change in the gas flow in the transfer chamber 203. Further, in a case where the pressure difference between the transfer chamber 203 and the cooling chamber 204 becomes larger than 100 Pa, the purge gas supplied to the transfer chamber 203 may flow into the cooling chamber 204 more than necessary, causing a large change in the gas flow in the transfer chamber 203. In the following description, a case of controlling the pressure difference between the transfer chamber 203 and the cooling chamber 204 to be 10 Pa will be described.

First, a control when the internal pressure of the transfer chamber 203 is lowered by opening the gate valve 205 installed in the process chamber 201 will be described with reference to FIG. 9A.

As illustrated in FIG. 9A, for example, in a state where the gate valve 205 disposed in the process chamber 201 is closed while performing the in-furnace pressure and temperature adjustment step S803 to the modification step S805 in the substrate processing, the opening/closing valve 406 is closed such that the internal pressure of the transfer chamber 203 is 50 Pa and the internal pressure of the cooling chamber 204 is 40 Pa, and the MFC 403 is controlled so that the flow rate of the gas supplied from the gas supply nozzle 401 into the cooling chamber 204 is 100 slm (STEP 1).

For example, the substrate unloading step S806 or the like is performed from the state of STEP 1 and the transfer chamber pressure sensor 180 detects that the internal pressure of the transfer chamber 203 is lowered to reach 40 Pa by opening the gate valve 205 disposed in the process chamber 201 (STEP 2).

When the transfer chamber pressure sensor 180 detects a predetermined pressure value, the controller 121 opens the opening/closing valve 406 and performs a control such that the internal pressure of the cooling chamber 204 is lowered (STEP 3). At this time, the gate valve 205 remains opened.

After the state of STEP 3, for example, when the unloading process of the wafers 200 from the process chamber 201 is completed at the substrate unloading step S806, the gate valve 205 is closed. When the gate valve 205 is closed, the controller 121 closes the opening/closing valve and controls the pressure difference between the transfer chamber 203 and the cooling chamber 204 to keep a predetermined value (STEP 4).

By performing the control as described above, even when the internal pressure of the transfer chamber 203 is lowered by opening the gate valve 205, the internal pressure of the cooling chamber 204 is appropriately adjusted such that the pressure difference between the transfer chamber 203 and the cooling chamber 203 can be kept constant. Thus, it is possible to suppress deterioration in the film quality or deterioration in the throughput without disturbing the gas flow in the transfer chamber 203.

Next, a control when the internal pressure of the transfer chamber 203 rises by opening the gate valve 205 installed in the process chamber 201 will be described with reference to FIG. 9B.

As illustrated in FIG. 9B, for example, in a state in which the gate valve 205 disposed in the process chamber 201 is closed while performing the in-furnace pressure and temperature adjustment step S803 to the modification step S805 in the substrate processing, the opening/closing valve 406 is closed such that the internal pressure of the transfer chamber 203 is 50 Pa and the internal pressure of the cooling chamber 204 is 40 Pa, and the MFC 403 is controlled such that the flow rate of the gas supplied from the gas supply nozzle 401 into the cooling chamber 204 is 100 slm (STEP 5). Further, control of each part in this state is similar to the description of STEP 1 performed in FIG. 9A.

The transfer chamber pressure sensor 180 detects that the internal pressure of the transfer chamber 203 rises to reach 60 Pa by opening the gate valve 205 from the state of STEP 5 (STEP 6).

When the transfer chamber pressure sensor 180 detects a predetermined pressure value, the controller 121 increases the flow rate of the gas supplied from the gas supply nozzle 401 into the cooling chamber to 150 slm while remaining the opening/closing valve 406 closed, and controls the MFC 403 such that the internal pressure of the cooling chamber 204 rises (STEP 7).

When the internal pressure of the cooling chamber 204 reaches a predetermined value at STEP 7, the controller 121 closes the opening/closing valve, and controls the pressure difference between the transfer chamber 203 and the cooling chamber 204 to keep the predetermined value (STEP 8).

By performing the control as described above, even when the internal pressure of the transfer chamber 203 rises by opening the gate valve 205, the internal pressure of the cooling chamber 204 is appropriately adjusted such that the pressure difference between the transfer chamber 203 and the cooling chamber 203 can be kept constant. Thus, it is possible to suppress deterioration in the film quality and deterioration in the throughput without disturbing the gas flow in the transfer chamber 203.

In addition, in the present embodiment, there has been described a structure in which the gate valve that spatially isolates the transfer chamber 203 from the cooling chamber 204 is not installed. However, the present disclosure is not limited thereto, and even when the gate valve that spatially isolates the transfer chamber 203 from the cooling chamber 204 is installed on a sidewall of the cooling chamber 204, the pressure control in the cooling chamber described above may be performed. Further, a refrigerant pipe 409 through which a refrigerant flows may be installed on the sidewall surface of the cooling chamber 204 to improve a cooling efficiency.

In addition, in the present embodiment, it has been described that the microwave oscillator 655 is used as the heating device installed in the process chamber 201, but the present disclosure is not limited thereto. As the heating device installed in the process chamber 201, a heating device such as a lamp or the like may be used.

### (4) Effects according to the Present Embodiment

According to the present embodiment, one or more effects as set forth below may be achieved.

(1) The number of wafers 200 (two wafers) loaded from the pod 110 into the process chamber 201 by using the substrate transfer part 125 may be larger than the number of wafers 200 (one wafer) loaded from the process chamber 201 into the cooling chamber 204. By combining the one-wafer transfer and the two-wafer transfer of the wafers 200, it is possible to shorten the transfer time of the wafers 200.

(2) The number of wafers 200 (two wafers) loaded into the process chamber 201 by using the substrate transfer part 125 may be larger than the number of wafers 200 unloaded from the process chamber 201.

(3) The low temperature tweezers 125a-1 (low temperature substrate transfer part) and the high temperature tweezers 125a-2 (high temperature substrate transfer part) are installed at the substrate transfer mechanism 125 (the substrate transfer robot or the substrate transfer part). When the low-temperature wafers 200 are loaded into the process chamber 201 from the pod 110, two low-temperature wafers 200 are loaded into the process chamber 201 by using the low temperature tweezers 125a-1 and the high temperature tweezers 125a-2. When the high-temperature wafer 200 is loaded into the cooling chamber 204 from the process chamber 201, one high-temperature wafer 200 is loaded into the cooling chamber 204 by using the high temperature tweezers 125a-2.

(4) The heated (processed) high-temperature wafer 200 in the process chamber 201 can be moved to the CS 108 in the cooling chamber 204 by using the high temperature tweezers 125a-2 while keeping at a relatively high temperature, without being cooled in the process chamber 201. Thus, it is possible to improve the usage efficiency of the process chamber 201 and to improve the productivity in the modification process of the wafers 200, and the like.

(5) The cooling chamber 204 may be installed between the process chamber 201-1 and the process chamber 201-2. Thus, the moving distance (moving time) between the process chamber 201-1 and the cooling chamber 204 and the moving distance between the process chamber 201-2 and the cooling chamber 204 can be made equal to each other. Thus, it is possible to make the tact times equal to each other.

(6) By installing the cooling chamber 204 between the process chamber 201-1 and the process chamber 201-2, it is possible to improve the transfer throughput of the wafers 200.

(7) The CS 108 installed in the cooling chamber 204 is configured to be capable of holding four wafers 200. That is, the CS 108 is configured to be capable of cooling at least twice (4 wafers) the number of wafers 200 (2 wafers) heated in the process chamber 201-1 or 201-2. When two wafers 200 are heated (processed) on the boat 217 in the process chamber 201 in batch, the two high-temperature wafers 200 are mounted on the CS 108 one by one by the high temperature tweezers 125a-2. At this time, when two cooled wafers 200b are mounted on the CS 108, the two cooled wafers 200b are unloaded from the CS 108 to the pod 110 by the high temperature tweezers 125a-2 and the low temperature tweezers 125a-1. Thus, it is possible to shorten the time for which the high temperature tweezers 125a-2 hold the high-temperature wafers 200a, and to reduce the heat load on the transfer machine 125.

Although the present disclosure has been described above according to the embodiments, the aforementioned embodiments may be appropriately modified and used, and effects thereof may be achieved.

For example, in each of the aforementioned embodiments, there has been described a process of modifying the amorphous silicon film into the polysilicon film as the film containing silicon as the main component, but the present disclosure is not limited thereto and the film formed on the surface of the wafer 200 may be modified by supplying a gas containing at least one selected from the group of oxygen (O), nitrogen (N), carbon (C), and hydrogen (H). For example, in a case where a hafnium oxide film (HfxOy film) as a high dielectric film is formed on the wafer 200, a deficient oxygen in the hafnium oxide film can be replenished by supplying microwaves and heating the same while supplying a gas containing oxygen, thereby improving characteristics of the high dielectric film.

Further, although the hafnium oxide film is illustrated herein, the present disclosure is not limited thereto but may be suitably applied to a case where an oxide film containing a metal element containing at least one selected from the group of aluminum (Al), titanium (Ti), zirconium (Zr), tantalum (Ta), niobium (Nb), lanthanum (La), cerium (Ce), yttrium (Y), barium (Ba), strontium (Sr), calcium (Ca), lead (Pb), molybdenum (Mo), tungsten (W), and the like, that is, a metal-based oxide film, is modified. That is, the film-forming sequence described above may be suitably applied to a case where a TiOCN film, a TiOC film, a TiON film, a TiO film, a ZrOCN film, a ZrOC film, a ZrON film, a ZrO film, an HfOCN film, an HfOC film, an HfON film, an HfO film, a TaOCN film, a TaOC film, a TaON film, a TaO film, an NbOCN film, an NbOC film, an NbON film, an NbO film, an AlOCN film, an AlOC film, an AlON film, an AlO film, an MoOCN film, an MoOC film, an MoON film, an MoO film, a WOCN film, a WOC film, a WON film, or a WO film are modified on the wafer 200.

Further, not only the high dielectric film but also a film containing silicon doped with an impurity as a main component may be heated. As the film containing silicon as the main component, an Si-based oxide film, such as a silicon nitride film (SiN film), a silicon oxide film (SiO film) a silicon oxycarbide film (SiOC film), a silicon oxycarbonitride film (SiOCN film), a silicon oxynitride film (SiON) and the like, may be used. The impurity includes, for example, at least one selected from the group of bromine (B), carbon (C), nitrogen (N), aluminum (Al), phosphorus (P), gallium (Ga), arsenic (As), and the like.

Alternatively, a resist film based on at least one selected from the group of a methyl methacrylate resin (polymethyl methacrylate: PMMA), an epoxy resin, a novolac resin, a polyvinyl phenyl resin, and the like may be used.

Further, although one of the processes for manufacturing a semiconductor device has been described above, the present disclosure is not limited thereto but may be applied to a technique of processing a substrate, such as a patterning process in the process of manufacturing a liquid crystal panel, a patterning process in the process of manufacturing a solar cell, a patterning process in the process of manufacturing a power device, or the like.

According to the present disclosure in some embodiments, it is possible to provide an electromagnetic wave processing technique capable of suppressing a reduction in productivity even when a substrate cooling step is provided.

While certain embodiments have been described, these embodiments have been presented by way of example only, and are not intended to limit the scope of the disclosures. Indeed, the embodiments described herein may be embodied in a variety of other forms. Furthermore, various omissions, substitutions and changes in the form of the embodiments described herein may be made without departing from the spirit of the disclosures. The accompanying claims and their equivalents are intended to cover such forms or modifications as would fall within the scope and spirit of the disclosures.

What is claimed is:

1. A substrate processing apparatus, comprising:
at least one process chamber configured to heat substrates;
a cooling chamber configured to cool the substrates heated in the at least one process chamber; and
a transfer machine configured to transfer the substrates,
wherein the number of substrates loaded into the at least one process chamber by using the transfer machine is larger than the number of substrates loaded into the cooling chamber by using the transfer machine.

2. The substrate processing apparatus according to claim 1, wherein the number of substrates loaded into the at least one process chamber by using the transfer machine is larger than the number of substrates unloaded from the at least one process chamber by using the transfer machine.

3. The substrate processing apparatus according to claim 1, wherein the number of cooled substrates unloaded from the cooling chamber by using the transfer machine is larger than the number of substrates heated in the at least one process chamber and loaded into the cooling chamber by using the transfer machine.

4. The substrate processing apparatus according to claim 1, wherein the transfer machine includes at least one high temperature substrate transfer arm configured to transfer a high-temperature substrate and at least one low temperature substrate transfer arm configured to transfer a low-temperature substrate.

5. The substrate processing apparatus according to claim 4, wherein when the low-temperature substrate is loaded into the at least one process chamber, the low-temperature substrate is loaded into the at least one process chamber by using the at least one high temperature substrate transfer arm and the at least one low temperature substrate transfer arm, and
wherein when the high-temperature substrate is loaded into the cooling chamber, the high-temperature substrate is loaded into the cooling chamber by using the at least one high temperature substrate transfer arm.

6. The substrate processing apparatus according to claim 4, wherein when the low-temperature substrate is loaded into the at least one process chamber, the low-temperature substrate is loaded into the at least one process chamber by using the at least one high temperature substrate transfer arm and the at least one low temperature substrate transfer arm, and
wherein when the high-temperature substrate is unloaded from the at least one process chamber, the high-temperature substrate is unloaded from the at least one process chamber by using the at least one high temperature substrate transfer arm.

7. The substrate processing apparatus according to claim 4, wherein when the high-temperature substrate heated in the at least one process chamber is loaded into the cooling chamber, the high-temperature substrate is loaded by using the at least one high temperature substrate transfer arm, and
wherein when the low-temperature substrate cooled in the cooling chamber is unloaded from the cooling chamber, the low-temperature substrate is unloaded from the cooling chamber by using the at least one high temperature substrate transfer arm and the at least one low temperature substrate transfer arm.

8. The substrate processing apparatus according to claim 1, wherein the at least one process chamber includes at least two process chambers, and wherein the cooling chamber is installed between the process chambers.

9. The substrate processing apparatus according to claim 1, further comprising:
a transfer chamber in which the transfer machine is installed; and
a controller configured to perform a control such that an internal pressure of the transfer chamber is higher than an internal pressure of the cooling chamber.

10. The substrate processing apparatus according to claim 9, wherein the controller is further configured to perform a control such that a pressure difference between the transfer chamber and the cooling chamber is 10 Pa.

11. The substrate processing apparatus according to claim 1, wherein the cooling chamber is further configured to cool the substrates, wherein the number of substrates cooled in the cooling chamber is at least twice the number of substrates heated in the at least one process chamber.

12. The substrate processing apparatus according to claim 1, wherein a gas supply pipe configured to supply a cooling gas and an exhauster configured to exhaust the cooling gas are installed in the cooling chamber.

13. The substrate processing apparatus according to claim 4, wherein the at least one high temperature substrate transfer arm is made of a material having high heat resistance and low heat conductivity.

14. The substrate processing apparatus according to claim 4, wherein a mapping sensor is installed in the at least one low temperature substrate transfer arm.

15. The substrate processing apparatus according to claim 1, further comprising a microwave oscillator configured to supply microwaves into the at least one process chamber.

16. A method of manufacturing a semiconductor device, comprising:
loading substrates into a process chamber;
heating the substrates in the process chamber;
loading the substrates heated in the process chamber into a cooling chamber; and
cooling the heated substrates in the cooling chamber,
wherein the number of substrates loaded into the process chamber in the act of loading the substrates into the process chamber is larger than the number of substrates loaded into the cooling chamber in the act of loading the substrates heated in the process chamber into the cooling chamber.

17. The method according to claim 16, further comprising unloading the substrates cooled in the cooling chamber from the cooling chamber,
wherein the number of substrates unloaded from the cooling chamber in the act of unloading the cooled substrates from the cooling chamber is larger than the number of substrates loaded into the cooling chamber in the act of loading the heated substrates into the cooling chamber.

18. A non-transitory computer-readable recording medium storing a program that causes, by a computer, a substrate processing apparatus to perform a process, the process comprising:
loading substrates into a process chamber;
heating the substrates in the process chamber;
loading the substrates heated in the process chamber into a cooling chamber; and
cooling the heated substrates in the cooling chamber,
wherein the number of substrates loaded into the process chamber in the act of loading the substrates into the process chamber is larger than the number of substrates loaded into the cooling chamber in the act of loading the substrates heated in the process chamber into the cooling chamber.

19. The non-transitory computer-readable recording medium according to claim 18, further comprising unloading the substrates cooled in the cooling chamber from the cooling chamber,
wherein the number of substrates unloaded from the cooling chamber in the act of unloading the cooled substrates from the cooling chamber is larger than the number of substrates loaded into the cooling chamber in the act of loading the heated substrates into the cooling chamber.
